(19) United States
(12) Patent Application Publication
(10) Pub. No.: US 2012/0012897 A1
(43) Pub. Date: Jan. 19, 2012

(54) Vertically Fabricated BEOL Non-Volatile Two-Terminal Cross-Trench Memory Array with Two-Terminal Memory Elements and Method of Fabricating the Same

(75) Inventors: PAUL BESSER, SUNNYVALE, CA (US); ROBIN CHEUNG, CUPERTINO, CA (US); WEN ZHONG KONG, NEWARK, CA (US)

(73) Assignee: UNITY SEMICONDUCTOR CORPORATION, SUNNYVALE, CA (US)

(21) Appl. No.: 13/185,410

(22) Filed: Jul. 18, 2011

Related U.S. Application Data
(60) Provisional application No. 61/399,741, filed on Jul. 16, 2010.

(51) Int. Cl. H01L 23/52

(52) U.S. Cl. 257/208; 257/E23.141

(57) ABSTRACT

A non-Flash non-volatile cross-trench memory array formed using an array of trenches formed back-end-of-the-line (BEOL) over a front-end-of-the-line (FEOL) substrate includes two-terminal memory elements operative to store at least one bit of data that are formed at a cross-point of a first trench and a second trench. The first and second trenches are arranged orthogonally to each other. At least one layer of memory comprises a plurality of the first and second trenches to form a plurality of memory elements. The non-volatile memory can be used to replace or emulate other memory types including but not limited to embedded memory, DRAM, SRAM, ROM, and FLASH. The memory is randomly addressable down to the bit level and erase or block erase operation prior to a write operation are not required.

### CROSS-REFERENCE TO RELATED APPLICATIONS

This application is related to pending U.S. patent application Ser. No. 12/661,678, Filed on Mar. 22, 2010, and titled “Immersion Platinum Plating Solution” and to U.S. patent application Ser. No. 12/454,322, Filed on May 15, 2009, now U.S. Published Application No. 2010/0159688, and titled “Device Fabrication”, U.S. patent application Ser. No. 11/095,026, filed Mar. 30, 2005, and published as U.S. Pub. No. 2006/0171200, and entitled “Memory Using Mixed Valence Conductive Oxides”, U.S. patent application Ser. No. 12/653,836, filed Dec. 18, 2009, and published as U.S. Pub. No. 2010/0157658, and entitled “Conductive Metal Oxide Structures In Non-Volatile Re-Writable Memory Devices”; U.S. Pat. No. 7,897,951, issued on Mar. 1, 2011, and entitled “Continuous Plane Of Thin-Film Materials For A Two-Terminal Cross-Point Memory”; and U.S. patent application Ser. No. 12/653,851, filed Dec. 18, 2009, and published as U.S. Pub. No. 2010/0159641, and entitled “Memory Cell Formation Using Ion Implant Isolated Conductive Metal Oxide”, U.S. patent application Ser. No. 11/881,473, filed Jul. 26, 2007, and published as U.S. Pub. No. 2009/0027976, and entitled “Threshold Device For A Memory Array”; and U.S. Pat. No. 7,884,349, issued on Feb. 8, 2011, and entitled “Selection Device for Re-Writable Memory”, all of which are hereby incorporated by reference in their entirety for all purposes.

### FIELD OF THE INVENTION

The present invention relates generally to integrated circuits, and more specifically to non-volatile memory.

### BACKGROUND

Conventional cross-point memory arrays, including two-terminal cross-point arrays, use a plurality of conductive array lines that are typically are denoted as word lines and bit lines. The word lines are electrically isolated from one another and are arranged parallel to one another. Similarly, the bits lines are electrically isolated from one another and are arranged parallel to one another and are also oriented in a direction that is orthogonal to the direction of the word lines. A memory cell is positioned at an intersection of one of the word lines with one of the bit lines. For two-terminal memory cells, one terminal is electrically coupled with its respective word line and the other terminal is electrically coupled with its respective bit line. Data operations (e.g., read, write, program, erase) to a selected memory cell comprises applying an appropriate access voltage (e.g., a read voltage or a write voltage) across its respective word and bit lines.

In some conventional cross-point array structures the thin film layers of material that form the memory cell are patterned and etched using microelectronics fabrication techniques that are well understood in the microelectronics art. For some of those thin film layers, the fabrication processes (e.g., etching) and or chemicals used in the processing (e.g., hydrogen, fluorine) can damage or have a deleterious effect on one or more of the thin-film layers and result in defective memory cells. Further, electrically coupling the word and bit lines with active circuitry configured to perform data operations on the memory cells requires vias and the like. Each via can require its own photo mask and processing steps to form the via. Each mask layer includes a large NRE cost and each processing step adds cost and the real possibility of inducing a yield reducing defect in the array. Moreover, typically some or all of thin film layers that form the memory cell require patterning and etching and those patterning and etching steps require additional mask layers and can induce defects that reduce device yield.

Accordingly, it is desirable to eliminate as many photo mask layers and processing steps as possible in order to reduce NRE costs, fabrication costs, and to increase device yield. For some conventional memory structures, the number of masks depends on the number of memory layers N that are to be fabricated such that the total number of masks needed is greater than or equal to 3N+1. Therefore, for four layers of memory (i.e., N=4), at least 3(4)+1=13 masks are required to fabricate the memory layers. If a via is required for each mask layer, the masks for each via adds 4 to the mask count for a total of at least 17 masks. It is desirable to reduce the number of masks required for the memory layers to less than 3N+1 to reduce NRE costs, to reduce the number of processing steps and their associated costs (e.g., materials and capital equipment), and to increase yield.

Furthermore, the number of masks required for the memory layers does not include the additional masks required for fabricating circuitry on a substrate (e.g., silicon wafer or die). Therefore, in scenarios where active circuitry is fabricated first as part of a front-end-of-the-line (FEOL) circuitry fabrication processes and the memory layer(s) are fabricated directly on top of and in direct contact with the FEOL substrate as part of a back-end-of-the-line (BEOL) memory fabrication process, there will be masks associated the FEOL processing and the BEOL processing. Accordingly, it is desirable to reduce the cost and complexity of the BEOL processing to the greatest extent possible.

There are continuing efforts to improve non-volatile memory structures, to reduce manufacturing costs and increase yields for non-volatile memory, and to improve non-volatile memory fabrication technology.

### BRIEF DESCRIPTION OF THE DRAWINGS

Various embodiments of the invention are disclosed in the following detailed description and the accompanying drawings:

FIG. 1 is a cross-sectional view depicting one example of BEOL memory portions and FEOL circuitry portions of a two-terminal cross-trench memory array;

FIGS. 2A-2F are cross-sectional views depicting several BEOL microelectronics processing steps for forming a plurality of first trenches in a dielectric material and steps to fill the trenches with electrically conductive materials that form a planar bottom electrode upon which thin-film layers of memory material will subsequently be deposited over;

FIGS. 3A-3C are cross-sectional views depicting several BEOL microelectronics processing steps for forming a plurality of second trenches in a dielectric material and steps to fill the second trenches with thin-film layers of memory material to form a plurality of two-terminal memory elements;

FIG. 3D is a top plan view of a two-terminal cross-trench memory array having a plurality of two-terminal memory elements formed at cross-points of the first plurality of trenches with the second plurality of trenches;

FIGS. 4A-4B are cross-sectional views depicting an alternate embodiment of cross-trench memory in which the bottom electrode protrudes outward of its dielectric material and a plurality of thin-film layers of memory material are conformally deposited in the second plurality of trenches over the bottom electrode;

FIG. 5A is a top plan view of a two-terminal cross-trench memory array and vias that electrically couple FEOL circuitry with the first and second plurality of trenches;

FIG. 5B is a cross-sectional view of one example of an elevator via configured to electrically couple FEOL circuitry with BEOL trenches.

FIGS. 6A-6H are cross-sectional views of depicting several BEOL microelectronics processing steps for forming a plurality of thin-film materials, including memory materials, in a second plurality of trenches that cross the first plurality of trenches to form the plurality of two-terminal memory elements;

FIGS. 7-9 are cross-sectional views depicting several BEOL microelectronics processing steps for forming additional trenches and their respective memory materials above previously fabricated trenches to form a multi-layer cross-trench memory array having multiple planes of cross-trench memory with a plurality of two-terminal memory elements in each memory plane;

FIG. 10A is a top-plan view of a layout of waffle pads and interconnect configured to electrically couple with a two-terminal cross-trench memory array;

FIG. 10B is a top plan view depicting a two-terminal cross-trench memory array having a first trench electrically coupled with a first waffle pad and as second trench electrically coupled with a second waffle pad;

FIGS. 11A and 11B are perspective drawings depicting a conductive metal oxide (CMO) based memory element including mobile oxygen ions which may be used to implement the memory elements of the memory arrays of the present invention, the drawing in FIG. 11A depicting an example of the CMO-based memory element in a low-resistance, erased state and the drawing in FIG. 11B depicting an example of the CMO-based memory element in a high-resistance, programmed state;

FIGS. 11C and 11D are perspective drawings depicting a CMO-based based memory element in an erased and programmed state respectively, during a read operation where a read voltage is applied across the terminals of the memory element to generate a read current;

FIG. 11E depicts top plan views of a wafer processed FEOL to form a plurality of base layer die including active circuitry and an electrical interconnect structure and the same wafer subsequently processed BEOL to integrally form one layer or multiple layers of memory and their respective memory elements directly on top of the base layer die where the finished die can subsequently be singulated, tested, and packaged into integrated circuits; and

FIG. 11F depicts a graphical representation of an example of a non-linear I-V characteristic for a discrete memory element with integral selectivity.

Although the above-described drawings depict various examples of the invention, the invention is not limited by the depicted examples. It is to be understood that, in the drawings, like reference numerals designate like structural elements. Also, it is understood that the drawings are not necessarily to scale.

### DETAILED DESCRIPTION

Various embodiments or examples may be implemented in numerous ways, including as a system, a process, an apparatus, or a series of program instructions on a computer readable medium such as a computer readable storage medium or a computer network where the program instructions are sent over optical, electronic, or wireless communication links. In general, operations of disclosed processes may be performed in an arbitrary order, unless otherwise provided in the claims.

A detailed description of one or more examples is provided below along with accompanying figures. The detailed description is provided in connection with such examples, but is not limited to any particular example. The scope is limited only by the claims, and numerous alternatives, modifications, and equivalents are encompassed. Numerous specific details are set forth in the following description in order to provide a thorough understanding. These details are provided as examples and the described techniques may be practiced according to the claims without some or all of the accompanying details. For clarity, technical material that is known in the technical fields related to the examples has not been described in detail to avoid unnecessarily obscuring the description. The described fabrication techniques may be varied and are not limited to the examples provided.

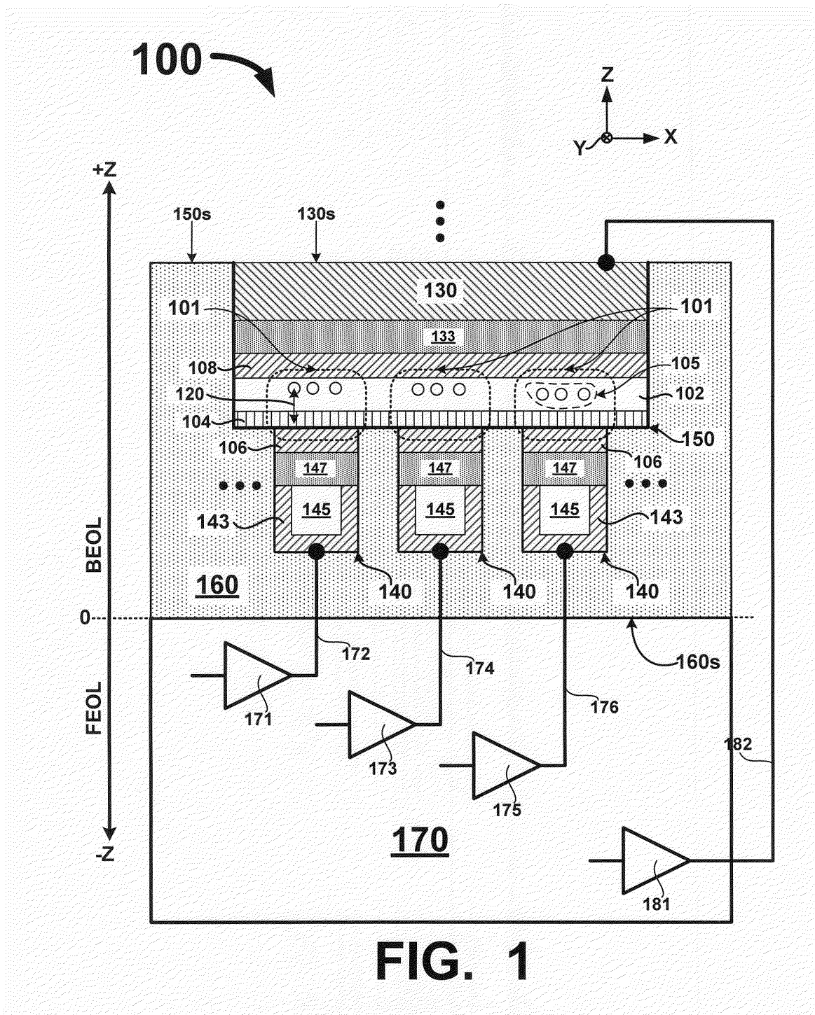

FIG. 1 depicts an exemplary cross-sectional view of an integrated circuit that includes a front-end-of-the-line (FEOL) circuitry portion that can be fabricated on a substrate such as a silicon wafer and can include circuitry configured for data operations on memory such as a randomly accessed non-volatile memory that does not require an erase operation prior to a write operation and data stored in the memory can be randomly accessed in segments as small as a bit, several bits, a nibble, a byte, a page, or a block. In some examples, the substrate comprises a die that has been singulated (e.g., sawed or cut) from a larger substrate (e.g., a silicon wafer) containing a plurality of the die. The substrate can be connected with a suitable package for an integrated circuit.

The integrated circuit includes in contact with the substrate and fabricated directly above the substrate a back-end-of-the-line (BEOL) memory portion that is electrically coupled with the circuitry in the FEOL portion. A point 0 on a Z-axis demarcates the BEOL portion positioned along a +Z axis and the FEOL portion (e.g., circuitry and FEOL-to-BEOL interconnect portion) positioned along a −Z axis, and therefore positioned below the BEOL portion which is fabricated in contact with and directly above the FEOL portion of the substrate. The FEOL active circuitry includes but is not limited to driver circuitry 171-181. Drivers 171-175 can be bit-line drivers and driver 181 can be a word-line driver. Other FEOL circuitry for controlling, accessing, and sensing data is not depicted in FIG. 1. An interconnect structure (172, 174, 176, 182) that spans the FEOL and BEOL layers electrically couples the drivers 171-181 with bit-line trenches (140) and a word-line trench (150) that are positioned orthogonal to each other. Although only three bit line trenches 140 are depicted there can be more or fewer bit line trenches 140 than depicted. Similarly, although only one word line trench 150 is depicted, here can be more or fewer word line trenches 150 than depicted. For example, the additional bit line trenches 140 can be disposed along the ±X-axis (e.g., to the left and right of the drawing sheet) and additional word line trenches 150 can be disposed along the ±Y-axis (e.g., into and out of the drawing sheet). The present invention is not limited to the designation of the trenches (140, 150, etc.) described herein as word lines or bit lines and that designation will be application dependent. For example, trenches 140 can be word lines and trenches 150 can be bit lines.

A non-volatile two-terminal memory element 101 is formed at a cross-point of the trenches (140, 150). A portion of the word-line trench 150 and a portion of the bit-line trench 140 are operative as the first and second terminals of each memory element 101. As will be described in greater detail below, appropriated access voltage potentials applied by driver circuitry 171-181 are operative to select one or more memory elements 101 for a data operation such as a read, write, program, or erase operation. Program and erase operations are types of write operations that change a state (e.g., a conductivity profile) of non-volatile data stored in the memory elements 101. However, unlike conventional FLASH memory, the memory elements 101 do not require an erase operation prior to a write operation and data can be written to a plurality of the memory elements 101 configured in the cross-trench array configuration without performing a block erase operation that is required by FLASH memory. Moreover, a FLASH operating system (FLASH OS) is not required to manage data operations, such as the erase before writes and block erase operations on the plurality of memory elements 101.

In FIG. 1, a dielectric material 160, such as silicon oxide (SiO₂) of silicon nitride (SiNx) can be patterned and etched to form a plurality of first trenches 140 (e.g., trenches 140 running in a direction that is into and out of the page ±Y-axis for FIG. 1). Structures in the trench 140 include but are not limited to a liner or cladding 143 (e.g., made from titanium nitride (TiN)), a core conductor 145 (e.g., of copper (Cu) or tungsten (W)), a barrier material 147 (e.g., of palladium (Pd) or copper-tungsten-phosphorus (CWP)), and an electrode material 106 (e.g., a bottom electrode BE of platinum (Pt)), for example.

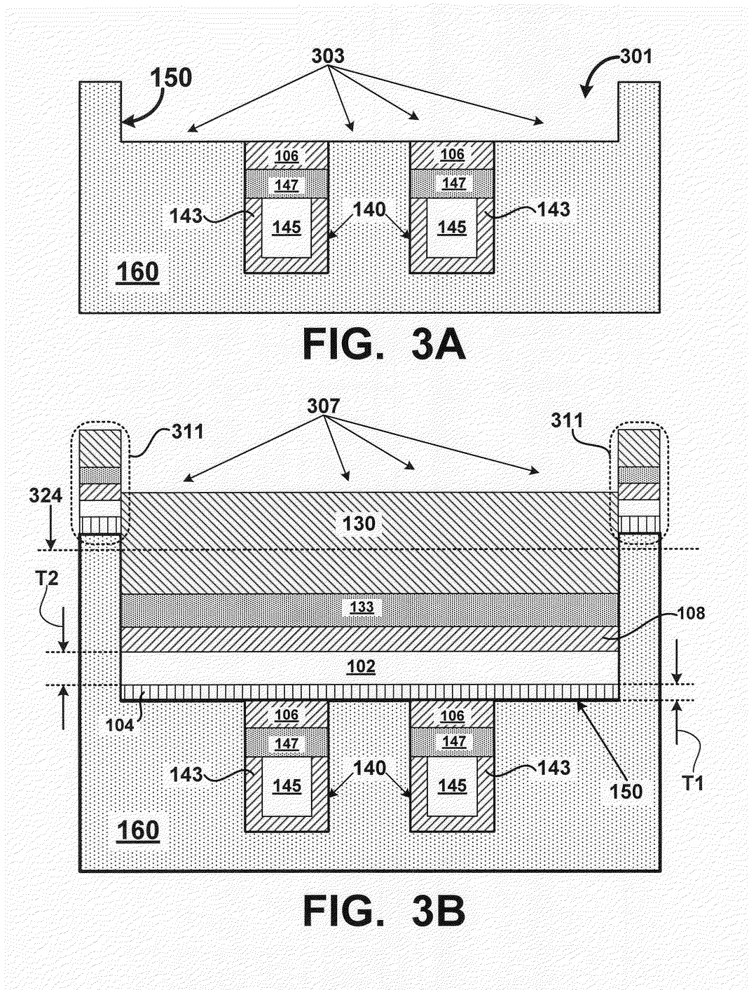

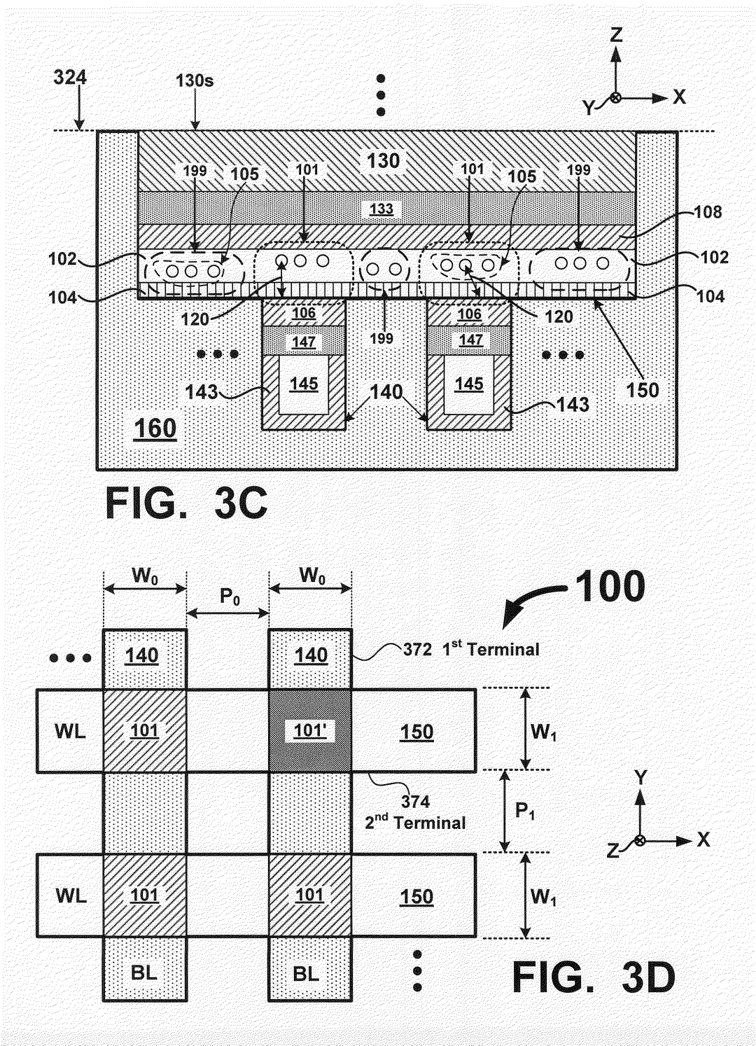

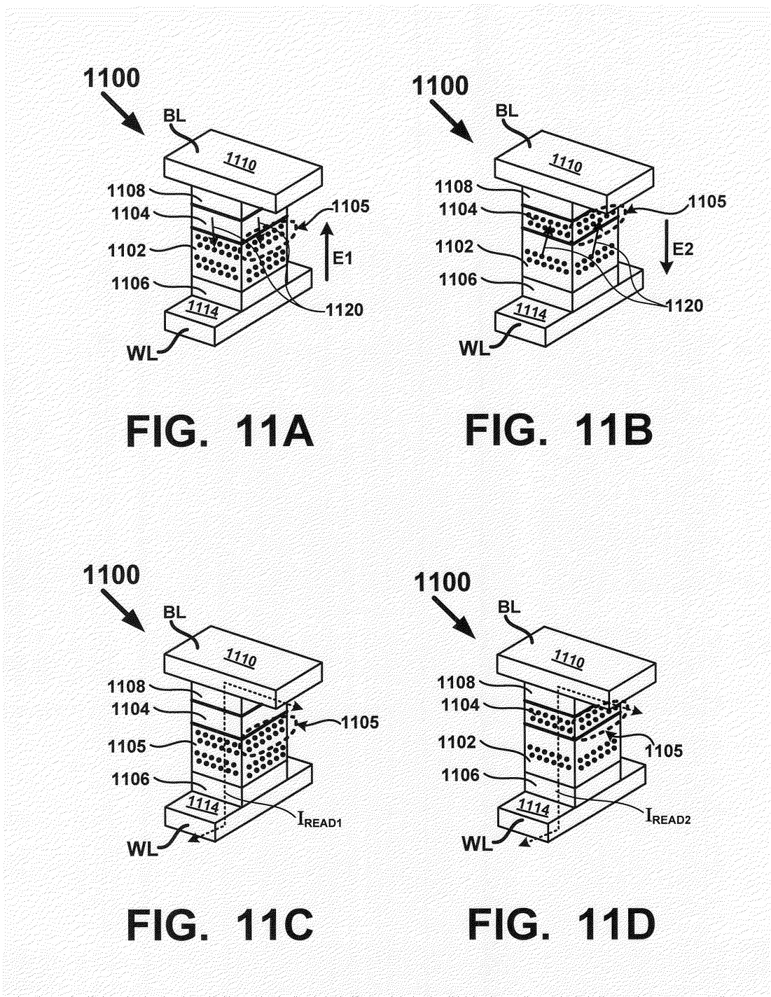

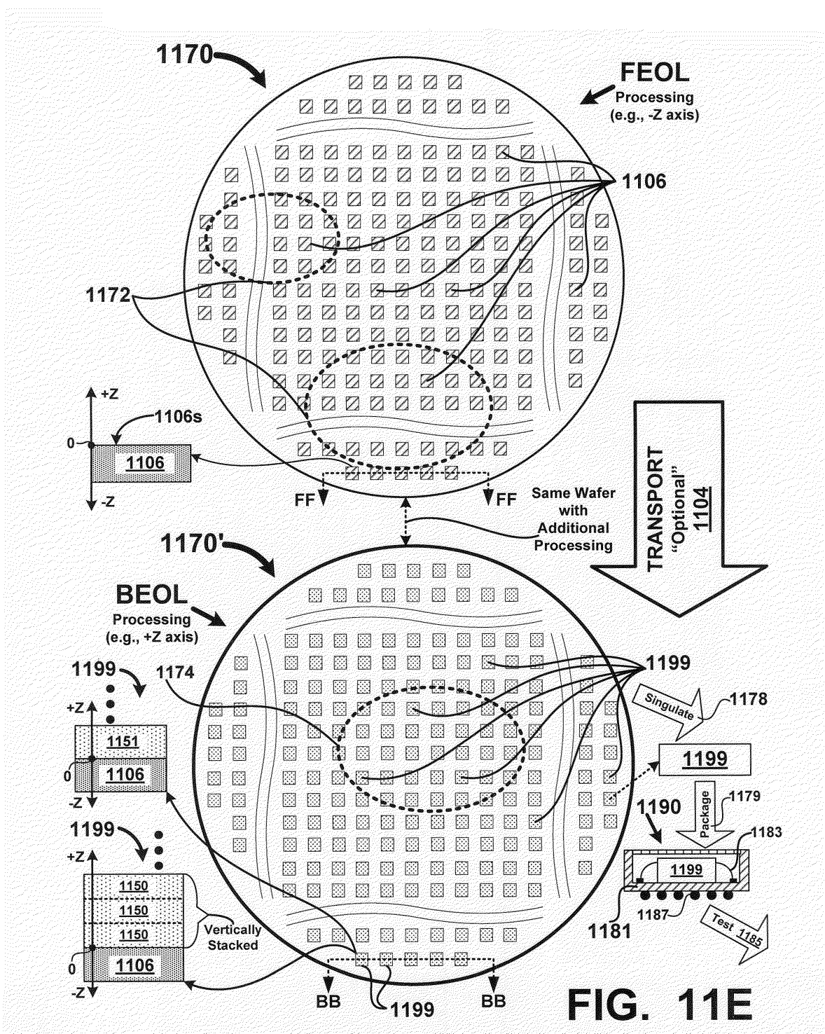

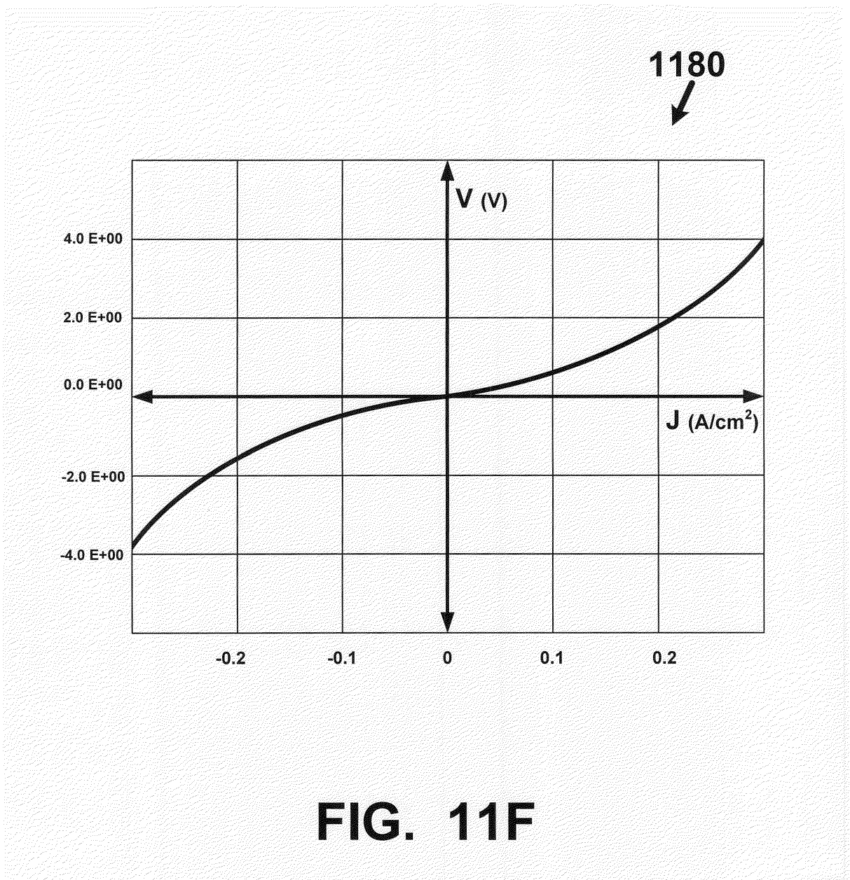

A second trench(s) 150 (e.g., running in a direction that is left-to-right on the page ±X-axis for FIG. 1 and substantially orthogonal to the first trenches 140). The trench 150 includes deposited therein a plurality of thin film materials including but not limited to an insulating metal oxide (IMO) layer 104 having a substantially uniform thickness that is less than 50 Å (see thickness T1 in FIG. 3B) and in contact with a portion of the BE 106 one or more conductive metal oxide (CMO) layers 102 typically having a combined thickness of less than 500 Å (see thickness T2 in FIG. 3B) in contact with the IMO layer, an electrode layer 108 (e.g., a top electrode TE) of an electrically conductive material (e.g., platinum Pt) in contact with the CMO layer, an adhesion layer 133 (e.g., titanium nitride—TiN) in contact with the TE 108, and a conductor 130 (e.g., a word-line of Cu or W). When a plurality of CMO layers 102 are used (not shown), each CMO layer is in contact with an adjacent CMO layer, the IMO layer 104 is in contact with one of the CMO layers and the TE 108 is in contact with another one of the CMO layers. The CMO layer 102 includes mobile oxygen ions 105, at least a portion of the mobile oxygen ions 105 are transported 120 between the CMO layer(s) 102 and the IMO layer 104 in response to an electric field (not shown) during write operations to one or more selected memory elements 101 (see memory elements 1100 in FIGS. 11A-11D).

In FIG. 1 a cross-sectional view depicts a dielectric layer (e.g., SiO₂) in the BEOL portion (+Z-Axis) that includes the aforementioned trenches (140, 150). Although only three trenches 140 are depicted and one trench 150 is depicted, the actual number of trenches will be application dependent and is some examples there can be several thousand to several million trenches depending on the size of the memory array(s). Embedded memory arrays (e.g., kilobytes or megabytes of data storage) can be smaller than memory arrays used for mass storage (e.g., gigabytes of data storage). Furthermore, although a single layer of BEOL memory is depicted, additional layers of BEOL memory can be vertically fabricated along the +Z-Axis above upper surfaces 150s and 130s as will be described in greater detail below.

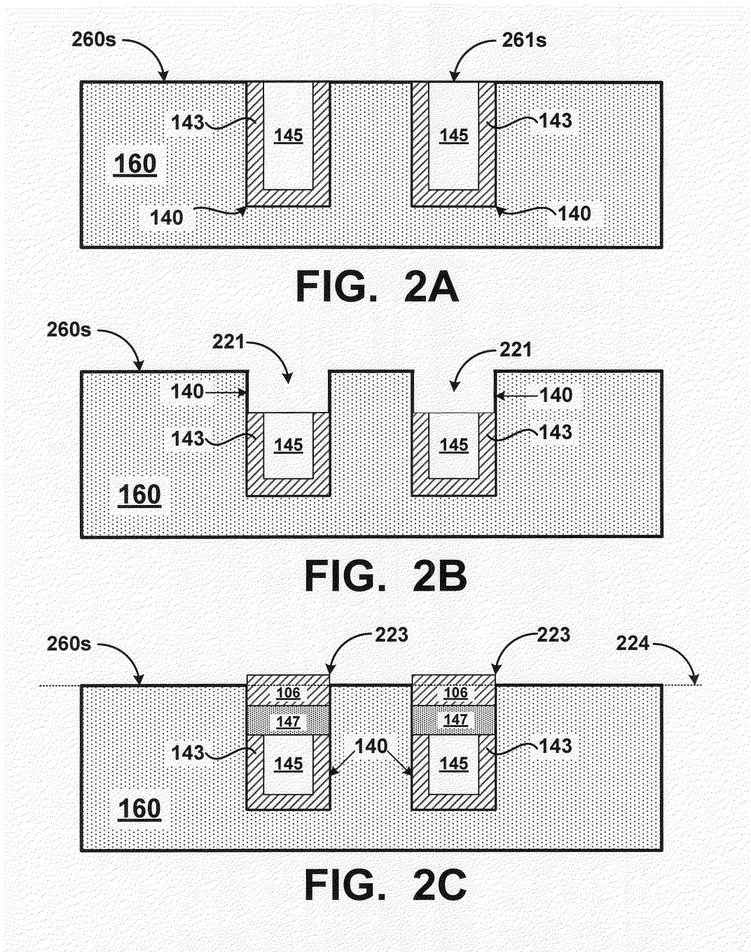

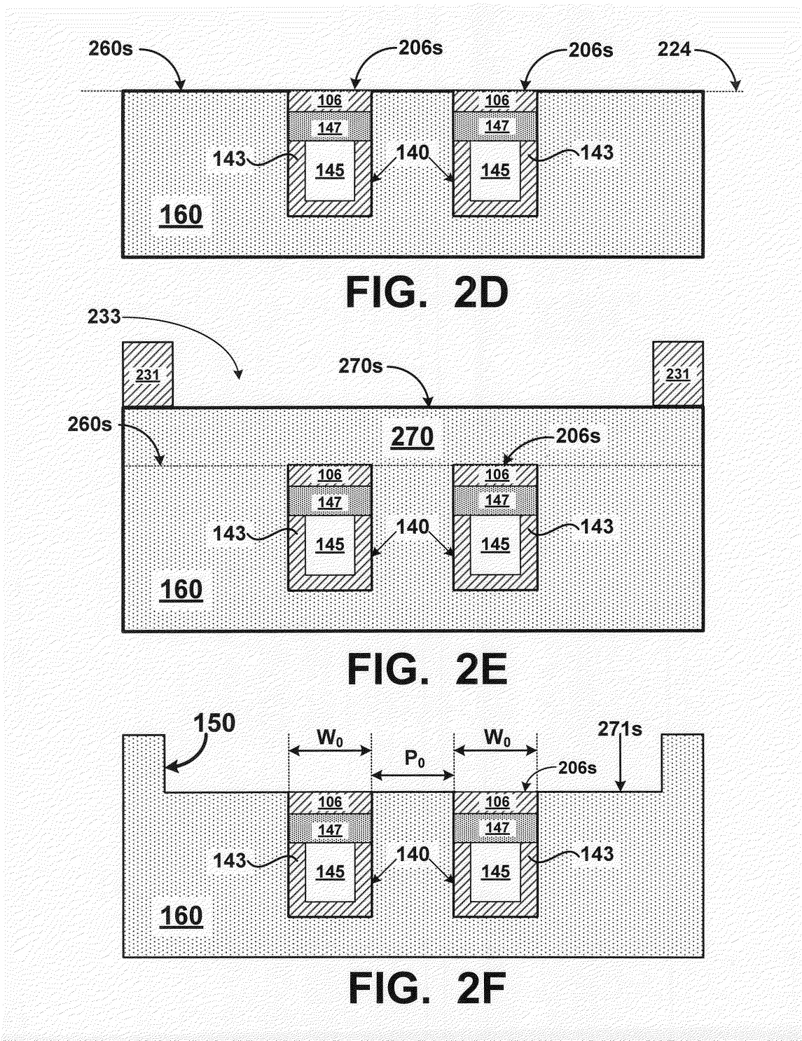

In FIG. 2A a cross-sectional view depicts the structure of FIG. 1 after an etching step (e.g., a wet etch) to recess previously deposited interconnect materials 145 and 143 below an upper surface 260s of dielectric 160 such that those materials recess inward of an upper surface 261s of trenches 140 and form an opening 221 in the dielectric layer 160 as depicted in FIG. 2B. Subsequently, in FIG. 2C an electrically conductive barrier layer material 147 and a bottom electrode material 106 are deposited in the openings of trench 140. The barrier layer material 147 can be formed using electroless plating of a material including but not limited to palladium Pd, cobalt-tungsten-phosphorus CWP, nickel-boron NiB, and nickel-phosphorus NiP, for example. The BE 106 can be formed using an immersion platinum Pt plating process that is operative to form a thin and continuous film of Pt on a metal surface, such as the metal surface of the barrier layer material 147. The immersion plated Pt will adhere to the barrier layer material 147 but not to the material of the dielectric layer 160. A thickness for the immersion plated Pt for the BE 106 can be less than 100 Å, for example. The immersion Pt plating process can be controlled to produce the desired thickness for the BE 106 while also using the minimal amount of expensive Pt to obtain the desired thickness. A top electrode (TE) as will be described below, can also be formed using the immersion Pt plating process described in U.S. patent application Ser. No. 12/661,678, Filed on Mar. 22, 2010, and titled “Immersion Platinum Plating Solution”, already incorporated herein by reference. After deposition, material for the BE 106 may protrude 223 outward of the trench 140 and above surface 260s. In subsequent process steps, the BE 106 can be planarized (e.g., using CMP) to provide a substantially planar upper surface upon which to deposit subsequent thin-film materials for the memory elements 101. Dashed line 224 represents an amount of the material that can be removed from the BE 106 to bring the material substantially planar with upper surface 260s or some other reference point. In FIG. 2D, BE 106 has been planarized and a surface 206s of the BE 106 is substantially planer with surface 260s.

In FIG. 2E, additional dielectric material 270 (e.g., SiNx or SiO2) is deposited over surfaces 260s and 206s and completely covers those surfaces. Subsequently, the additional dielectric material 270 is planarized to form a substantially uniform upper surface 270s and is then patterned 231 (e.g., using photo resist or other mask material) and etched down to a predetermined distance (e.g., down to surface 206s) to form a second trench 150 that is orthogonal to the first trenches 140 and to expose upper surface 206s of the TE 106, as depicted in FIG. 2F. Here, upper surface 271s is substantially planar with upper surface 206s of the TE's 106.

Trenches 140 can be space apart from one another by a regular and repeating pitch P₀ and each trench 140 can have identical or substantially identical widths W₀. In some applications W₀ and P₀ can be identical or substantially identical (e.g., 45 nm or less). Although not shown in the cross-section view of FIG. 2F, trench(s) 150 can also be space apart from one another by a regular and repeating pitch P₁ and each trench 150 can have identical or substantially identical widths W₁. In some applications W₁ and P₁ (see top-plan view of trenches 150 in FIG. 3D) can be identical or substantially identical (e.g., 45 nm or less).

In FIG. 3A a cross-sectional view depicts an opening 301 in trench 150 that will subsequently be filled 303 with a plurality of thin-film materials that will cover trenches 140 and form a plurality of two-terminal memory elements at a cross-point of trenches 140 and 150. In FIG. 3B, a thin-film layer of an insulating metal oxide (IMO) material 04 is deposited in trench 150 and a portion of the IMO layer 104 is in contact with BE 106. Here, a thickness T1 of the IMO layer 104 is approximately less than 50 Angstroms (e.g., in a range from about 5 \acute{Å} to about 35 \acute{Å}). Next one or more layers of a conductive metal oxide material 102 are deposited on top of the IMO 104 to a thickness T2 that is typically 500 Angstroms or less. Moreover, typically T2>T1. A layer of an electrically conductive material for the TE 108 is deposited on the CMO layer 102 (e.g., the upper most CMO layer if more than one CMO layer is used). The TE 108 can be made from platinum (Pt) and may be formed in a manner similar to the BE 106 (e.g., immersion plated Pt). An electrically conductive barrier layer material 133 is deposited on the CMO 102, followed by deposition of an electrically conductive material 130 on top of the barrier layer material 133. The barrier layer material 133 can be made from a material including but not limited to titanium nitride—TiN or tantalum nitride—TaN and the electrically conductive material 130 can be made from a material including copper—Cu or tungsten—W, or alloys of those materials.

In FIG. 3B, as a result of the deposition of the above mentioned thin-film materials in trench(s) 150, a field area 311 outside of the area for the core cross-trench array includes excess thin-film materials that must be removed. Accordingly, in FIG. 3C, a planarization process (e.g., CMP) is used to remove the excess thin-film materials from field areas 311. For example, the structure depicted in FIG. 3B can be planarized down to a dashed line 324 such that an upper surface 130s of layer 130 is substantially planar with dashed line 324 and the excess thin-film materials have been completely removed.

In FIG. 3C, contact of the BE 106 in trenches 140 with the thin-film materials (e.g., the IMO 104, CMO 102, and TE 108) in trench(s) 150 forms a two-terminal memory element 101 at cross-points between trenches 140 and 150 as depicted in top plan view in FIG. 3D. Here, looking down the Z-axis, two-terminal cross-trench array 100 includes bit-line (BL) trenches 140 run along the Y-axis and word-line (WL) trenches 150 run along the X-axis. A two-terminal memory element 101 is formed between a crossing of one of the BL trenches 140 and WL trenches 150. Although only two WL and BL are depicted, as mentioned above, there can be more WL and BL than depicted in FIG. 3D.

The respective BL and WL for each memory element 101 are operative as first 372 and second 374 terminals of the memory element 101. An access voltage for a data operation (e.g., read, write, program, erase) applied to first terminal 372 and second terminal 374 selects memory element 101′ for the data operation. Although the entire CMO layer 102 includes the mobile oxygen ions 105, only the mobile oxygen ions 105 disposed in the portions of the CMO layer 102 that are positioned between the cross-points of trenches 140 and 150 are transported 120 between the IMO 104 and CMO 102 layers of the memory elements 101 during write operations (e.g., program and erase operations). Essentially, the electric field (see E1 and E2 in FIGS. 11A and 11B) that causes the transport 120 of the mobile ions 105 exists between the BE 106 and TE 106 of each memory element 101 (e.g., in the region proximately between the cross-points of a trench 140 with a trench 150). One advantage of the cross-trench array 100 is that the critical layers of the memory elements 101 (e.g., IMO 104, CMO 102, and TE 108) are deposited as substantially uniformly thick and planar thin-film layers starting with deposition of the IMO 104 and the substantially planar upper surface of BE 106 and resulting in a uniformly thick and planar IMO 104 layer upon which to deposit the CMO 102 so that the CMO 102 as deposited is also uniformly thick and planar without additional processing such as planarization and/or etching. Subsequently, the TE 108 is deposited on a planar and smooth CMO 104. Therefore, starting with a planar BE 106 promotes a favorable surface morphology for subsequently deposited thin-film layers for the memory elements 101. Furthermore, in a direction that each trench runs (e.g., along the ±X-axis or ±Y-axis) the layers for the memory materials (e.g., IMO, CMO, TE, BE) are continuous layers that are un-etched. Mobile oxygen ions 105 disposed in regions 199 of the CMO 102 (see 105 in regions 199 of FIG. 3C) that are not positioned between a cross-point of a BE and a TE are not affected by the electric field during write operations and therefore are not transported 120 between the IMO 104 and CMO 102 in those regions 199 (i.e., they remain substantially stationary in the CMO 102 of regions 199), namely because the electric field (e.g., E1, E2 in FIGS. 11A-11B) is substantially concentrated between the BE and the TE in the memory elements (101, 1100).

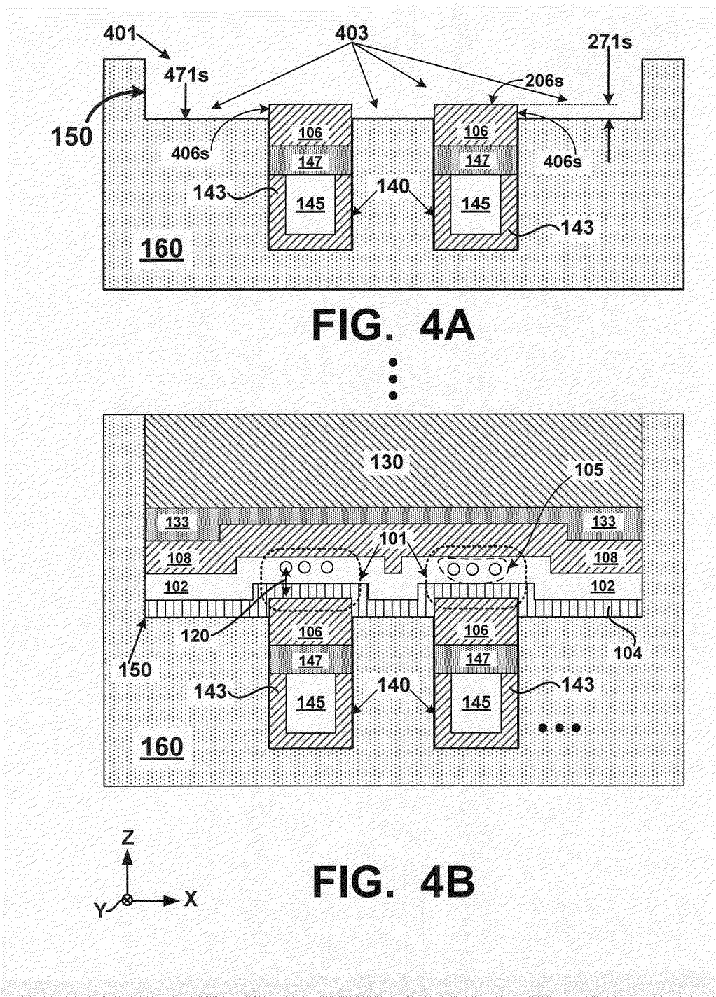

FIG. 4A depicts additional process step to recess the dielectric layer 160 below the upper planarized surface 206s of BE 106. The recess in dielectric layer 160 is operative to expose sidewall surfaces of the BE 106 so that subsequently deposited layers of thin film materials for the memory elements 101 contact a greater surface area of the BE 106 than would be the case if those materials were only deposited on the upper planarized surface 206s of the BE 106. Here, a dashed line 273 represents one example of how far below the upper planarized surface of the BE 106 the dielectric layer 160 can be recessed (e.g., down to a surface 473s) to expose sidewall surfaces 406s of the BE 106.

In FIG. 4B a cross-sectional view depicts the structure of FIG. 4A after a subsequent deposition of a plurality of thin-film materials 403 in opening 401 of trench 150 and directly on top of and completely covering the planar BE 106 in a manner similar to the deposition of materials 303 in FIGS. 3A-3C described above. The IMO 104 conformally covers the BE 106 and its sidewall surfaces 406s and each subsequently deposited layer (e.g., CMO 102 and TE 108) conformally covers the layer it is deposited on.

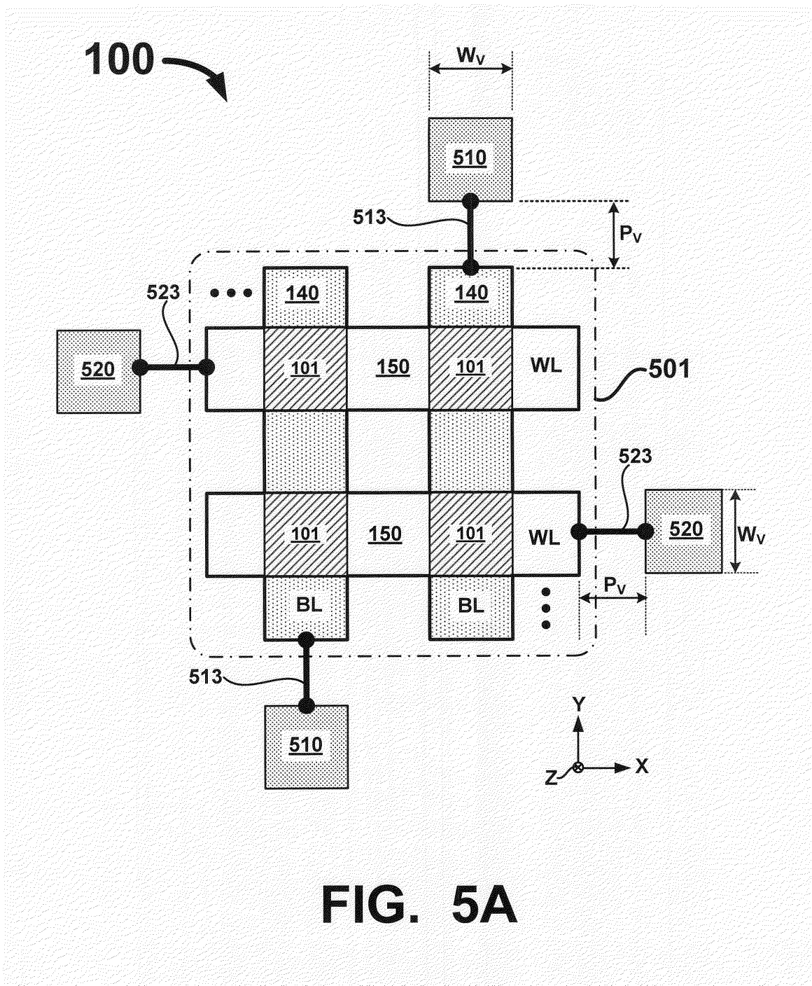

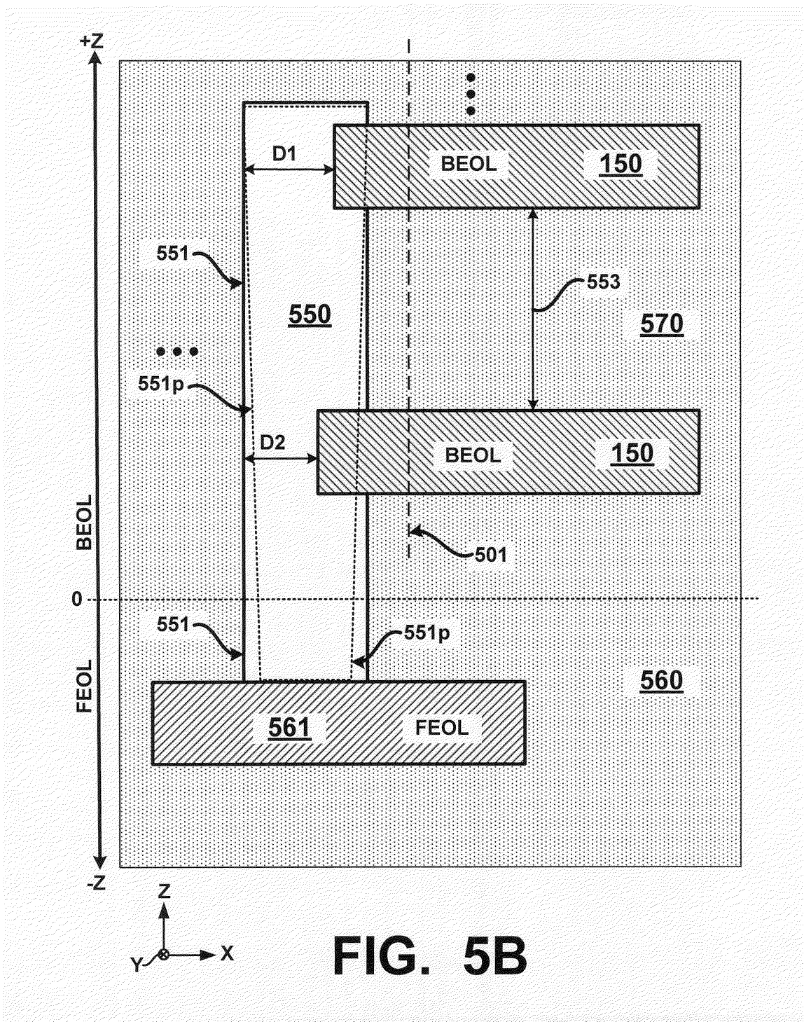

Turning now to FIG. 5, a top plan view depicts one example of how the WL and BL conductors in trenches 140 and 150 can be electrically coupled with active circuitry (e.g., drivers in FIG. 1) in the FEOL layer that is positioned below the BEOL memory layer. Here, cross-trench array 100 includes a core area denoted by dashed line 501 that includes the memory elements 101 and their respective WL 150 and BL 140 trenches. Outside of core area 501, the array 100 includes vias 510 and 520 that are electrically coupled (513, 523) with their respective WL 150 and BL 140 trenches. Vias 510 and 520 can have a width W_{V} and can be positioned a distance P_{V} from their respective trenches. Via widths W_{V} can be identical or substantially identical to the widths W₀ and/or W₁. The widths W_{V} of the vias need not be the same and can vary depending on the application. The distance P_{V} can be can be identical or substantially identical to the widths W₀, W₁, or W_{V}. The distance P_{V} can vary among the vias 510 and 520 and need not be the same of all vias. In FIG. 5A, WL vias 520 electrically couple 523 with their respective trenches 150 on alternating opposite sides of array 100. Similarly, BL vias 510 electrically couple 513 with their respective trenches 40 on alternating opposite sides of array 100. Positioning and electrical coupling of the vias with trenches is not limited to the example configurations depicted herein.

FIG. 5B depicts a cross-sectional view of one example of an elevator via 550 that electrically couples a plurality of trenches (WL trenches 150 are depicted) with circuitry in the FEOL layer (e.g., drivers of FIG. 1). A deep high aspect ratio via opening 551 can be formed (e.g., etched) in dielectric materials 570 and 560 to span the BEOL and FEOL layers and connects with a surface of a FEOL conductor 561. Via 551 opening can be filed with an electrically conductive material (e.g., tungsten—W) that complete fills via opening 551 to form via 550. Via opening 551 will likely have a sloped profile 551p that is wider at the top (e.g., in the BEOL portion) and narrower at the bottom (e.g., in the FEOL portion). The sloped profiled 551p can be due to the high aspect ratio of the opening 551 and etching properties and etch times for the etch material. As a result, elevator via 550 will be narrower at the bottom and will slope way from the trench conductors 150 and/or 140 in the BEOL portion. To compensate for the taper of the via 550, trench conductors 150 can be fabricated to have offset lengths that ensure each trench conductor 150 to be electrically coupled with via 550 makes contact with via 550. Here, lower trench conductor 150 can be configured to extend further out than upper trench conductor 150 so that distance D2 relative to via 550 is less than distance D1. In a multi-layer memory configuration, via 550 can be configured to connect with trenches on alternating layers of the array 100 such that trenches on even layers connect with via 550 and trenches on odd layers connect with a different elevator via (not shown).

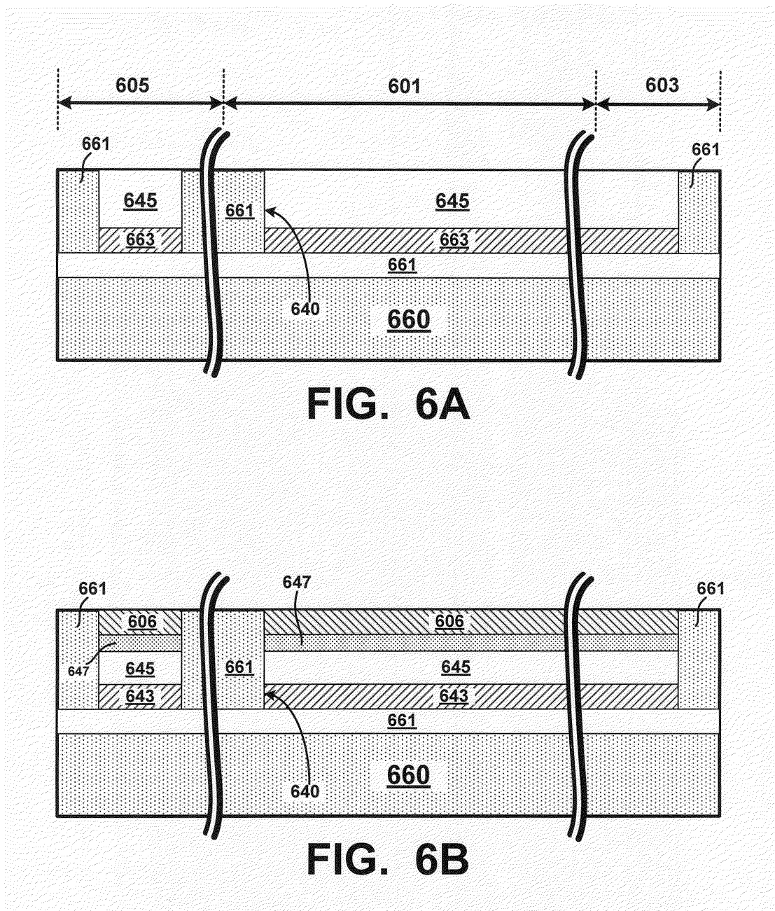

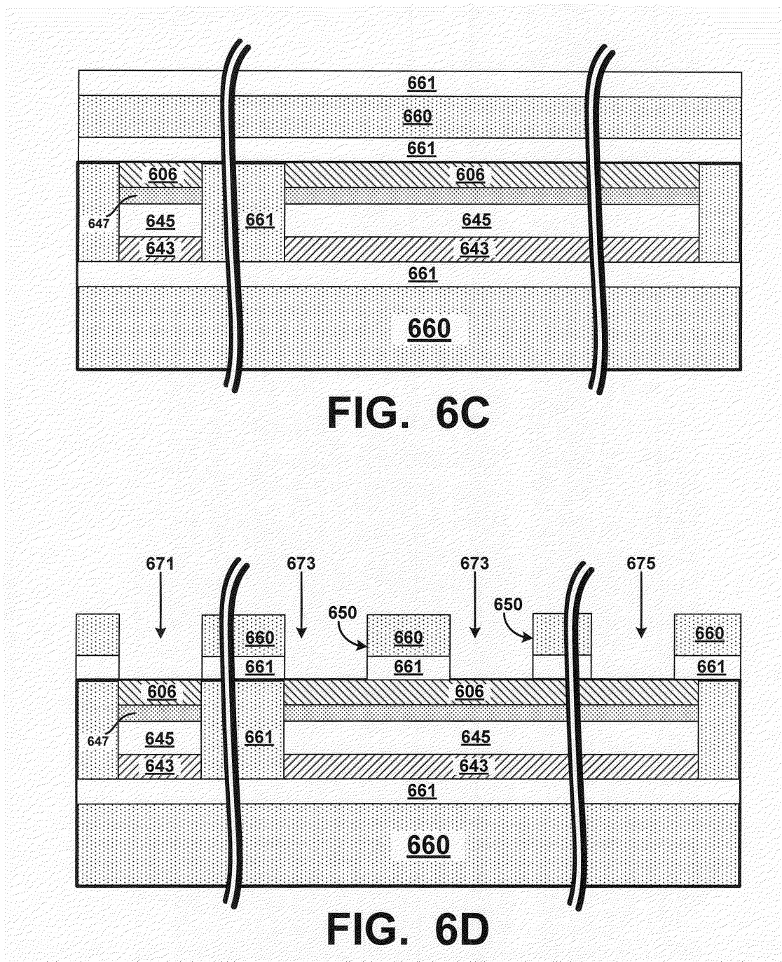

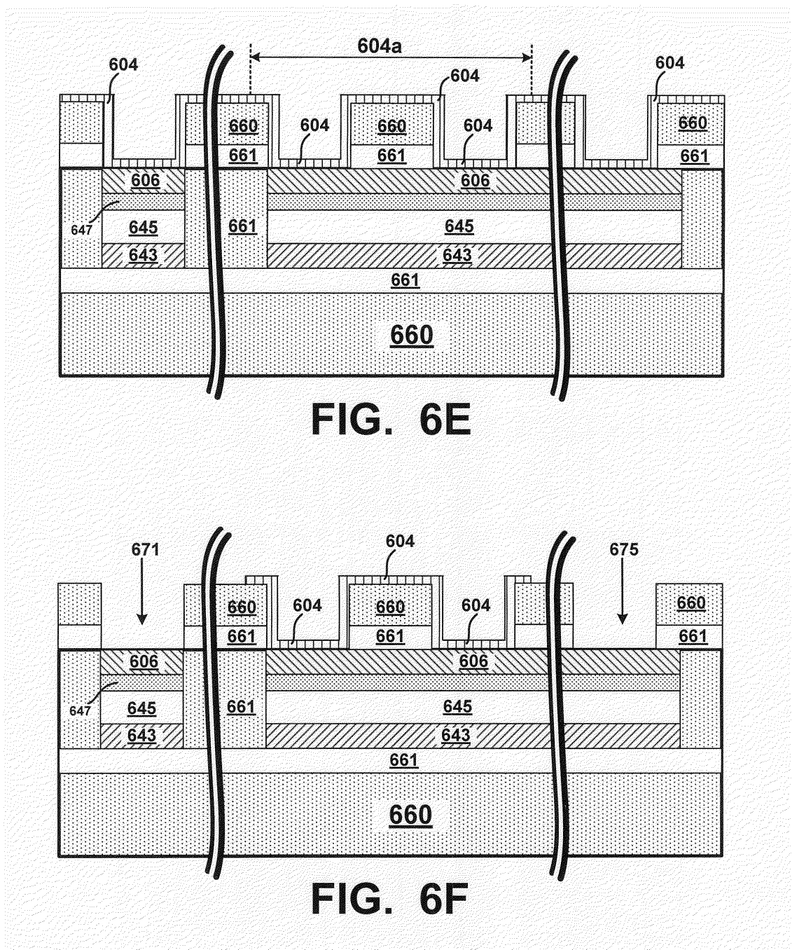

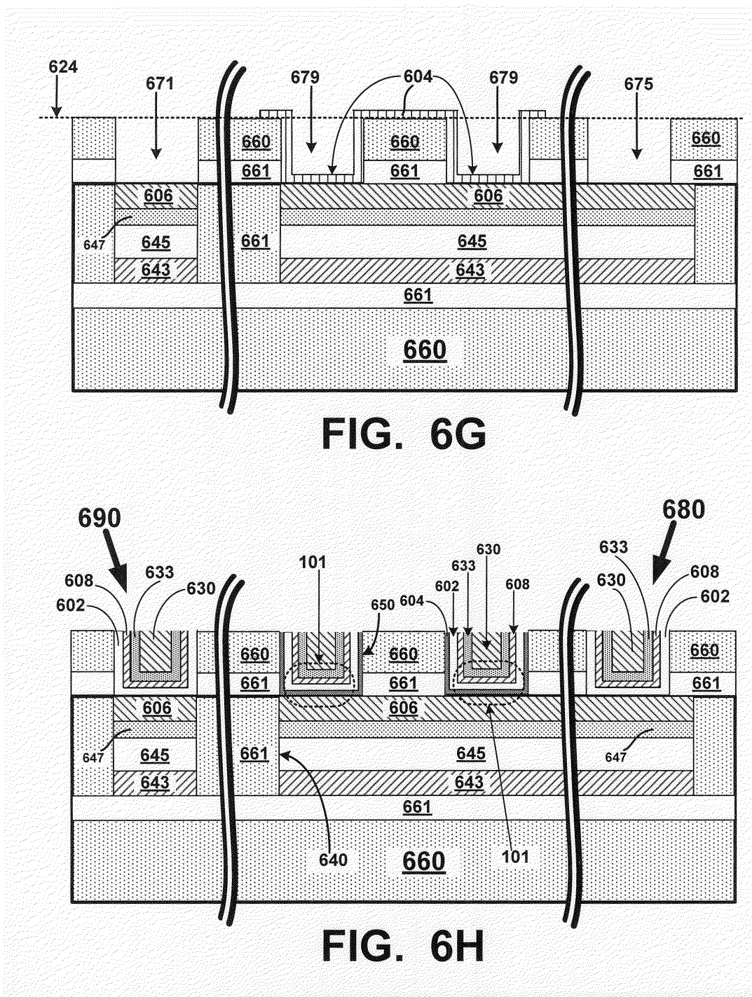

FIGS. 6A-6H depict cross-sectional views of fabrication steps for two-terminal memory elements of a two-terminal cross-trench-memory. In FIG. 6A, trenches for memory elements will be formed in array region 601 and outside of region 601 contacts can optionally be formed in regions 603 and 605 for electrically coupling access signals (e.g., for data operations or device testing using ATE) to specific word line and bit line trenches in the array. Here, materials 645 and 663 are already formed in trench 640 and in FIG. 6B they are etched to recess material 645 to accommodate deposition of materials 647 (e.g., a barrier layer) and 606 (e.g., a Pt BE). Similarly, materials for a contact (WL or BL) are formed in region 605. In FIG. 6C, layers of dielectric material 661 and 660 are deposited and in FIG. 6D, those layers (660, 661) are patterned and etched to form openings 671-675 for trenches 650 that are orthogonal to trenches 640. Trenches at openings 671 and 675 are for contacts and openings 673 are trenches for memory elements to be formed in subsequent steps.

In FIG. 6E, a thin-film layer of IMO 604 is conformally deposited in the trenches 650 and covers planar surface of BE 606. A mask material such a photo resist or the like (not shown) is used to cover IMO 604 in region 604a so that IMO 604 outside of region 604a is removed in a subsequent etching step so that no IMO 604 remains in the trenches for the contacts as depicted in FIG. 6F where IMO 604 is removed from openings 675.

In FIG. 6G, the structure is planarized to dashed line 624 to remove IMO 604 from upper surfaces so that the IMO 604 is positioned on bottom and sidewall surfaces of the trenches 650. In FIG. 6H, the remaining thin-film materials are deposited in the trenches (CMO 602, TE 608, barrier layer 633, and core conductor 630). Here, contact trenches include the deposited layers sans the IMO 604. Trenches in the array area now include memory elements 101 formed at a cross point of trench 640 with trench 650. A contact 680 (e.g., a WL Contact) and a contact 690 (e.g., a BL contact) are formed outside of the array area and configured to provide electrical access to the WL and BL trenches of the array 100.

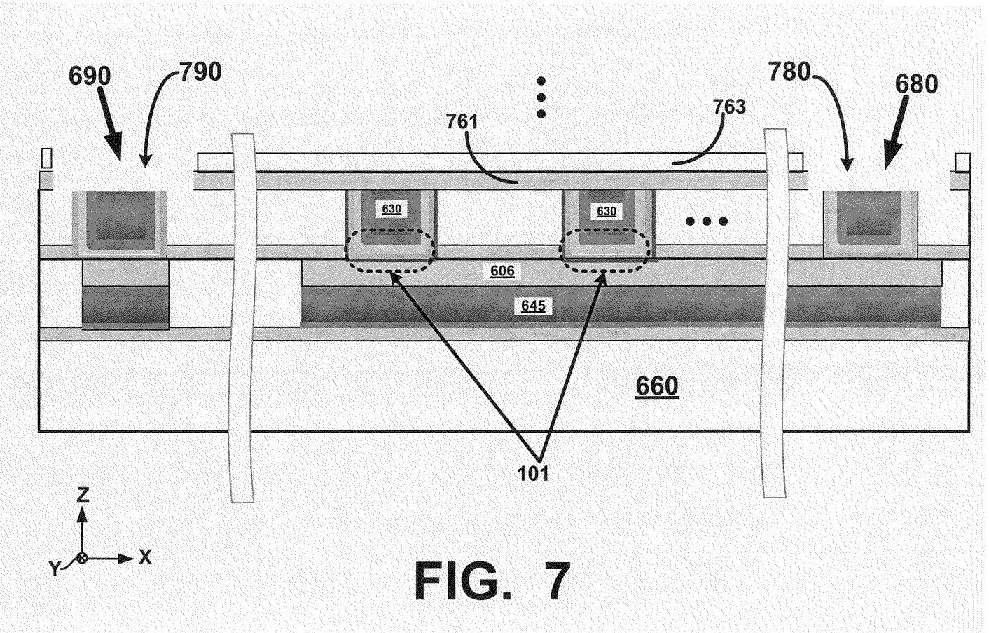

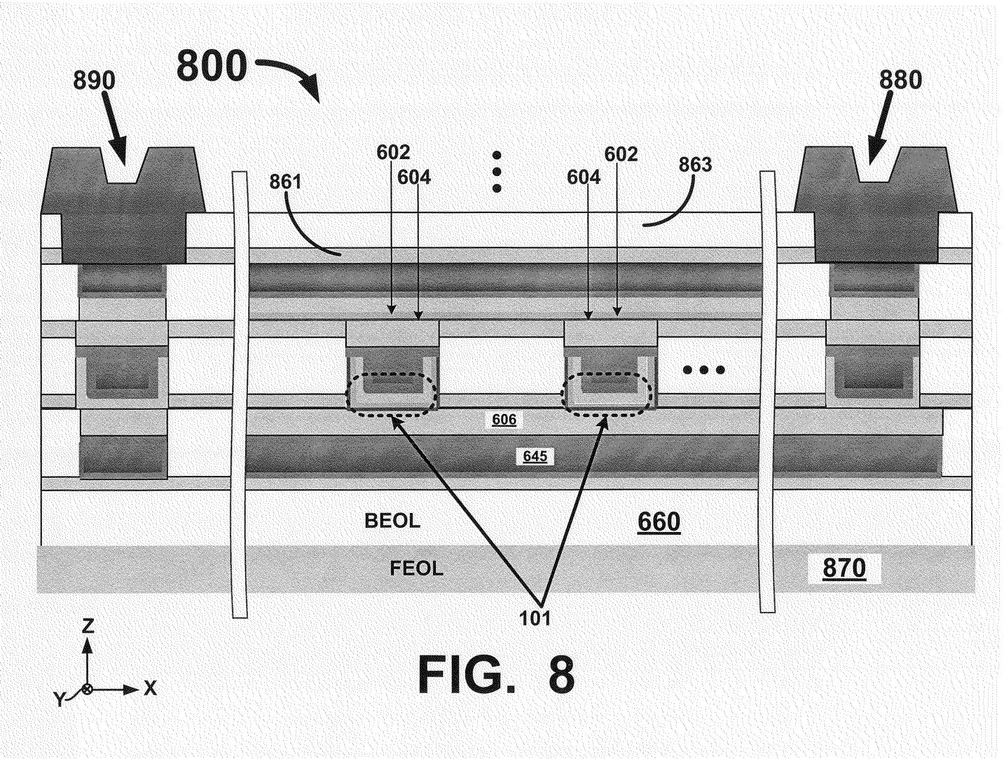

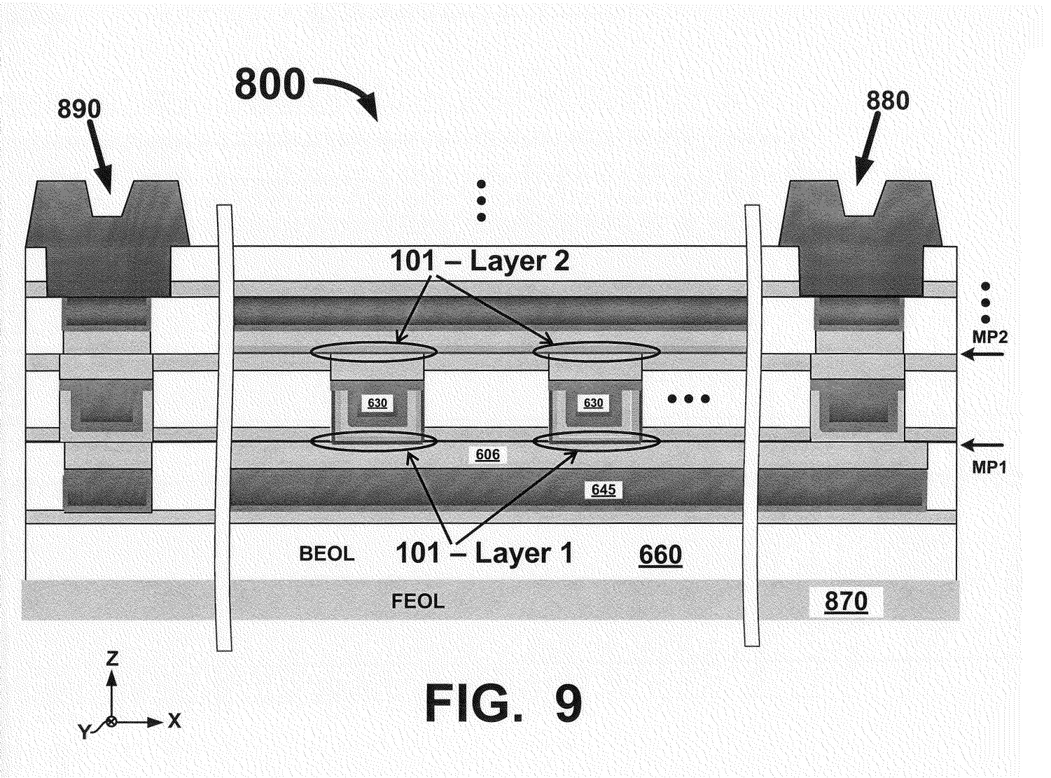

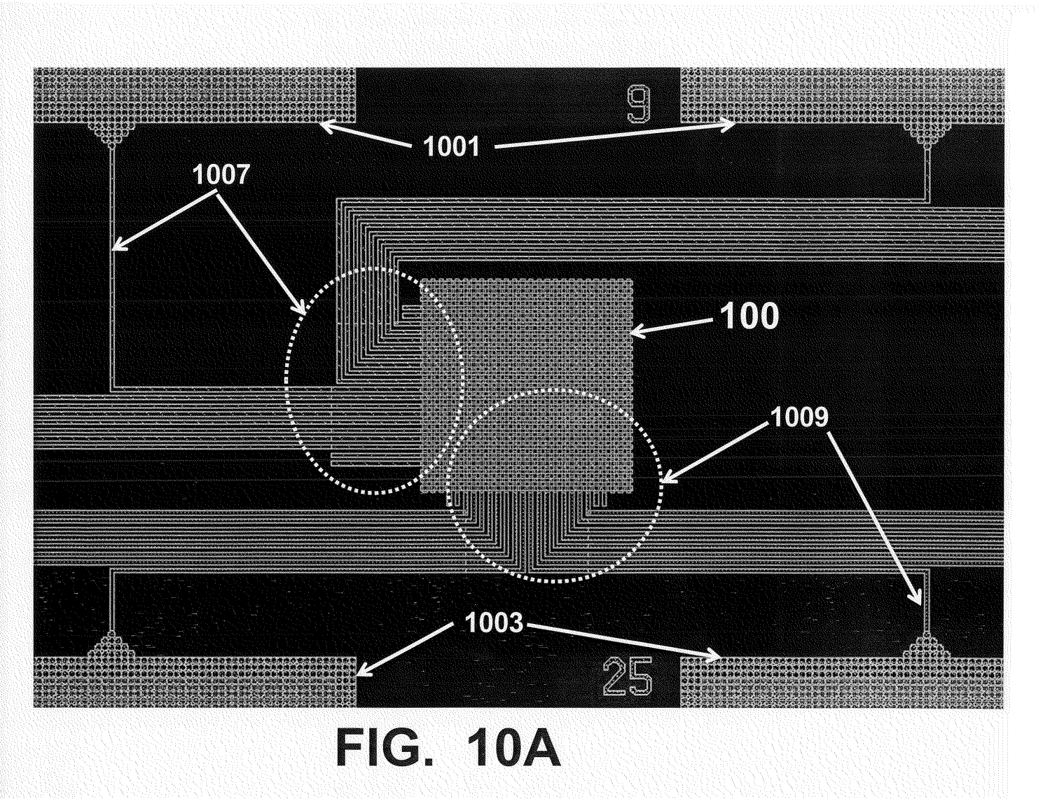

FIGS. 7-9 depict fabrication steps for forming multi-layer cross-trench memory arrays. Here, additional dielectric layers 761 and 763 are deposited over the structure depicted in FIG. 6H and openings 780 and 790 are formed in those layers to expose contacts 680 and 690. FIG. 8 depicts a second trench orthogonal to trenches 650 having an IMO 604 in contact with a BE 604 formed over the trenches 650, and subsequent thin-film layers to form a second layer of memory elements 101 over the first layer of memory element 101 as depicted in FIG. 9. Here, the first layer of memory elements 101 comprises one memory plane MP1 and the second layer of memory elements 101 comprises a second memory plane MP2. Additional layers/planes of memory can be formed by repeating the process described for additional layers. Here also, contacts 880 and 890 are completely formed and can be used to test the array for functionality etc., or to perform data operations. In some embodiments, the contacts 880 and 890 can be eliminated and access to the array 100 can be through vias or the like as described above.

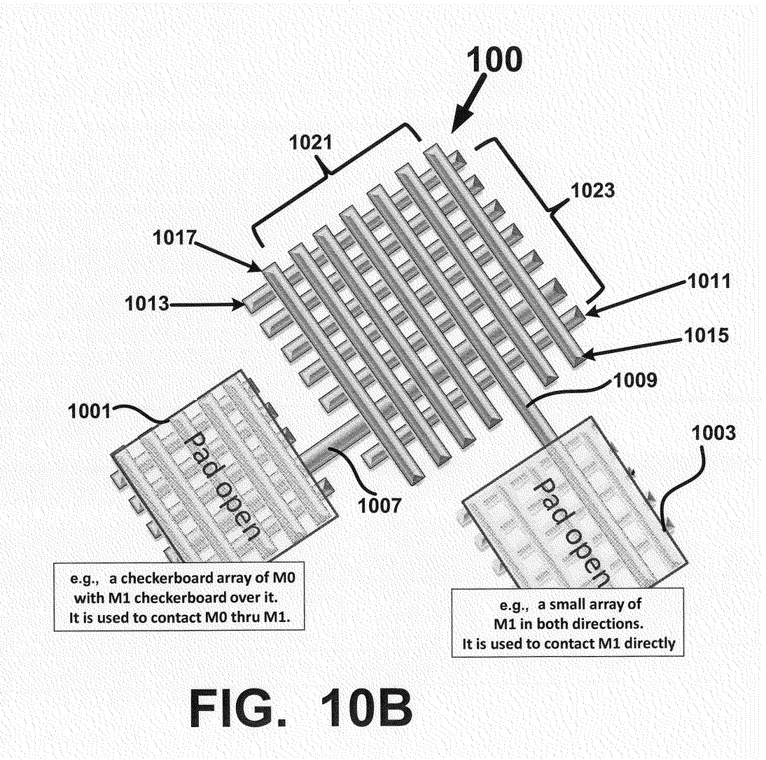

FIG. 10A is a top plan view of waffle pads 1001 and 1003 that are electrically coupled 1007 and 1009 with trenches of cross-trench memory array 100. Waffle pads 1001 and 1003 and their associated interconnect can be fabricated BEOL and used for probing the array 100 for testing and/or data operations. Waffle pads 1001 and 1003 present large surface areas compared with the dimensions of the WL and BL trenches and provide a generous area for tester probes or the like to electrically communicate with the array 100 and its memory elements 101.

In FIG. 10B, waffle pads can comprise an array of orthogonally oriented array lines that are electrically coupled 1007 and 1009 with BL trenches 1023 or WL trenches 1021 of array 100. Waffle pad 1001 can comprise a checkerboard array of Metal 0 (M0) with an array of Metal 1 (M1) checkerboard over the M0 checkerboard and can be used to electrically couple M0 (BL trenches 1023) through M1. Waffle pad 1003 can comprise a checkerboard array of M1 in both directions and can electrically couple M1 (WL trenches 1021) on array 100 directly. The waffle pads can be configured to electrically couple with a first end 1011 or second end 1013 of the BL's 1023 or a first end 1015 or a second end 1017 of the WL's 1021.

FIGS. 11A and 11B are perspective drawings of one example of a CMO-based memory element 1100 that can be used to implement the memory elements 101 of memory arrays 100 of various embodiments of the present invention. FIG. 11A depicts the CMO-based memory element 1100 in an erased state where mobile oxygen ions 1105 that were previously transported from the CMO 1102 into the IMO 1104 are transported 1120 back into the CMO 1102 to change a conductivity profile of the memory element 1100 to the erased state (e.g., a low resistance state). FIG. 11B depicts the CMO-based memory element 1100 in a programmed state where a portion of the mobile ions 1105 in the CMO 1102 are transported 1120 into the IMO 1104 to change the conductivity profile of the memory element to the programmed state (e.g., a high resistance state). The CMO-based memory element 1100 comprises a multi-layered structure that includes at least one CMO layer 1102 that includes mobile oxygen ions 1105. An insulating metal oxide (IMO) layer 1104 is in contact with the CMO layer 1102. The CMO layer 1102 is electrically coupled with a bottom electrode 1106 and the IMO layer 1104 is electrically coupled with a top electrode 1108 such that the CMO layer 1102 and IMO layer 1104 are electrically in series with each other and with the top and bottom electrodes 1108 and 1106. For example, when configured in one of the cross-trench memory arrays 100 of the present invention, the bottom electrode 1106 is electrically coupled with one of the WLs 1114 of the memory array and the top electrode 1108 is electrically coupled with one of the BLs 1110.

The CMO layer 1102 comprises an ionic conductor that is electrically conductive and includes mobile oxygen ions 1105. The material for the CMO layer 1102 can have a crystalline structure (e.g., single crystalline or polycrystalline) and the crystalline structure does not change due to data operations on the memory element 1100. For example, read and write operations to the memory element 1100 do not alter the crystalline structure of the CMO layer 1102. In other embodiments, the CMO layer 1102 can have an amorphous structure or a blended structure that is a combination of amorphous and crystalline. In either case, the structure is not changed by data operations on the memory element 1100.

The IMO layer 1104 comprises a high-k dielectric material having a substantially uniform thickness approximately less than 50 Angstroms and is an ionic conductor that is electrically insulating. The IMO layer 1104 is operative as a tunnel barrier that is configured for electron tunneling during data operations to the memory element 1100 and as an electrolyte to the mobile oxygen ions 1105 and is permeable to the mobile oxygen ions 1105 during write operations to the memory element 1100 such that during write operations oxygen ions 1105 are transported 1120 between the CMO and IMO layers 1102 and 1104.

In various embodiments, in regards to the layers 1102 and 1104 of FIGS. 11A-D, the layer 1102 can include one or more layers of a conductive metal oxide material, such as one or more layers of a conductive metal oxide-based (“CMO-based”) material, for example. The CMO material is selected for it properties as a variable resistive material that includes mobile oxygen ions and is not selected based on any ferroelectric properties, piezoelectric properties, magnetic properties, superconductive properties, or for any mobile metal ion properties. In various embodiments, layer 1102 can include but is not limited to a manganite material, a perovskite material selected from one or more the following: PrCaMnO_{X} (PCMO), LaNiO_{X} (LNO), SrRuO_{X} (SRO), LaSrCrO_{X} (LSCrO), LaCaMnO_{X} (LCMO), LaSrCaMnO_{X} (LSCMO), LaSrMnO_{X} (LSMO), LaSrCoO_{X} (LSCoO), and LaSrFeO_{X} (LSFeO), where x is nominally 3 for perovskites (e.g., x≦3 for perovskites) or structure 1102 can be a conductive binary oxide structure comprised of a binary metal oxide having the form A_{X}O_{Y}, where A represents a metal and O represents oxygen. The conductive binary oxide material may be doped (e.g., with niobium Nb, fluorine F, and/or nitrogen N) to obtain the desired conductive properties for a CMO.

In various embodiments, IMO layer 1104 can include but is not limited to a material for implementing a tunnel barrier layer and is also an electrolyte that is permeable to the mobile oxygen ions 1105 at voltages for write operations. Suitable materials for the layer 1104 include but are not limited to one or more of the following: high-k dielectric materials, rare earth oxides, rare earth metal oxides, yttria-stabilized zirconium (YSZ), zirconia (ZrO_{X}), zirconium oxygen nitride (ZrOxNy), yttrium oxide (YO_{X}), erbium oxide (ErO_{X}), gadolinium oxide (GdOx), lanthanum aluminum oxide (LaAIO_{X}), and hafnium oxide (HfO_{X}), aluminum oxide (AlOx), silicon oxide (SiOx), and equivalent materials. Typically, the layer 1104 comprises a thin film layer having a substantially uniform thickness of approximately less than 50 Angstroms (e.g., in a range from about Angstroms to about 35 Angstroms).

When in an erased state, as depicted in FIG. 11A, mobile oxygen ions 1105 (denoted by the small black-filled circles in FIGS. 11A-D) are concentrated in the CMO layer 1102 and the CMO-based memory element 1100 exhibits a low resistance to current (e.g., is in a low-resistance state). The CMO-based memory element 1100 is programmed to a programmed state (FIG. 11B) by applying a positive voltage across the top and bottom electrodes 1108 and 1106. The applied voltage creates an electric field E2 within the layers 1102 and 1104 that transports 1120 the oxygen ions 1105 from the CMO layer 1102 into the IMO layer 1104, causing the CMO-based memory element 1100 to conform to a high resistance, programmed state. When an erase voltage of reverse polarity is applied across the top and bottom electrodes 1108 and 1106, the mobile oxygen ions 1105 are transported 1120 back into the CMO layer 1102 (FIG. 11A) in response to electric field E1, returning the CMO-based memory element 1100 to a low-resistance, erased state. Writing data to the memory element 1102 does not require a prior erase operation and once data is written to the memory element 1100, the data is retained in the absence of electrical power. Although erase and program voltages have been described as examples of a write operation, writing data to the memory element 1100 requires application of write voltage potentials having an appropriate magnitude and polarity to the terminals of the memory element 1100 (e.g., applied to WL 1114 and BL 1110 of a selected memory element(s)). In FIGS. 11C and 11D, reading data stored in the memory element 1100 requires application of read voltage potentials having an appropriate magnitude and polarity to the terminals of the memory element 1100 (e.g., applied to WL 1114 and BL 1110 of a selected memory element(s)). The read voltage is operative to generate a read current I_{READ} that flows through the memory element 1100 while the read voltage is applied. The magnitude of the read voltage and the resistive value of the data stored in the selected memory element 1100 determine the magnitude of the read current I_{READ}. In FIG. 11C, the memory element 1100 is depicted in the erased state (e.g., low resistance state) and in FIG. 11D the memory element 1100 is depicted in the programmed state (e.g., high resistance state). Therefore, given the same magnitude of read voltage (e.g., 1.5V), the read current I_{READ1} will have a higher magnitude (e.g., due to the lower resistance state) depicted in FIG. 11C than the read current I_{READ2} depicted in FIG. 11D due to the higher resistance of the programmed state (i.e., I_{READ1}>I_{READ2}). Application of the read voltage does not cause mobile oxygen ion 1105 transport 1120 because the magnitude of the read voltage is less than the magnitude of the write voltage and therefore the read voltage does not generate an electric field having sufficient magnitude to cause mobile oxygen ion 1105 transport 1120 during read operations. Therefore, it is not necessary to re-write the data stored in the memory element 1100 after a read operation because the read operation is non-destructive to the stored data (e.g., does not corrupt or significantly disturb the stored data).

Once the CMO-based memory element 1100 is programmed or erased to either state, the memory element 1100 maintains that state even in the absence of electrical power. In other words, the CMO-based memory element 1100 is a non-volatile memory element. Therefore, no battery backup or other power source, such as a capacitor or the like, is required to retain stored data. The two resistive states are used to represent two non-volatile memory states, e.g., logic “0” and logic “1.” In addition to being non-volatile, the CMO-based memory element 1100 is re-writable since it can be programmed and erased over and over again. These advantages along with the advantage of being able to stack the two-terminal CMO-based memory elements in one or more memory layers above FEOL semiconductor process layers, are some of the advantages that make the CMO-based memory arrays of the present invention a viable and competitive alternative to other non-volatile memory technologies such as Flash memory. In other embodiments, the memory element 1100 stores two or more bits of non-volatile data (e.g., MLC) that are representative of more than two logic states such as: “00”; “01”; “10”; and “11”, for example. Those logic states can represent a hard-programmed state “00”, a soft-programmed state “01”, a soft-erased state “10”, and a hard-erased state “11”, and their associated conductivity values (e.g., resistive states). Different magnitudes and polarities of the write voltage applied in one or more pulses that can have varying pulse shapes and durations can be used to perform write operations on the memory element 1100 configured for SLC and/or MLC.

FIG. 11E is a top plan view depicting a single wafer (denoted as 1170 and 1170′) at two different stages of fabrication on the same wafer: FEOL processing on the wafer denoted as 1170 during the FEOL stage of microelectronics processing where active circuitry (e.g., CMOS circuitry) in logic layer 170 is fabricated on the substrate that comprises base layer die 1106 (e.g., a silicon wafer); followed by BEOL processing on the same wafer denoted as 1170′ during the BEOL stage of microelectronics processing where one or more layers (e.g., 1151 or 1150) of BEOL non-volatile memory are fabricated directly on top of the FEOL logic layer 170 (not shown) (e.g., on an upper surface 160s of the FEOL interlayer interconnect structure of FIG. 1). The single layer 1151 or multiple vertically stacked layers 1150 are not glued, soldered, wafer bonded, or otherwise physically or electrically connected with the base layer die 1106, instead they are grown directly on top of the base layer die 1106 so that they are integrally connected with the base layer die 1106 and with one another, are electrically coupled with the circuitry in the FEOL logic layer 170, thereby forming a unitary integrated circuit die 1199 that includes monolithically integrated FEOL and BEOL portions (e.g., inseparable FEOL circuitry and BEOL memory portions). Wafer 1170 includes a plurality of the base layer die 1106 formed individually on wafer 1170 as part of the FEOL process. As part of the FEOL processing, the base layer die 1106 may be tested 1172 to determine their electrical characteristics, functionality, yield, performance grading, etc. After all FEOL processes have been completed, the wafer 1170 is optionally transported 1104 for subsequent BEOL processing (e.g., adding one or more layers of memory such as single layer 1151 or multiple layers 1150) directly on top of each base layer die 1106. A base layer die 1106 is depicted in cross-sectional view along a dashed line FF-FF where a substrate (e.g., a silicon Si wafer) for the die 1106 and its associated active circuitry in logic layer 170 have been previously fabricated FEOL and are positioned along the −Z axis. For example, the one or more layers of memory (e.g., 1151 or 1150) are grown directly on top of an upper surface 1106s of each base layer die 1106 as part of the subsequent BEOL processing. Upper layer 1106s can be an upper planar surface 160s of the aforementioned interlayer interconnect structure operative as a foundation for subsequent BEOL fabrication of the memory layers along the +Z axis.

During BEOL processing the wafer 1170 is denoted as wafer 1170′, which is the same wafer subjected to additional processing to fabricate the memory layer(s) and their associated memory elements directly on top of the base layer die 1106. Base layer die 1106 that failed testing may be identified either visually (e.g., by marking) or electronically (e.g., in a file, database, email, etc.) and communicated to the BEOL fabricator and/or fabrication facility. Similarly, performance graded base layer die 1106 (e.g., graded as to frequency of operation) may identified and communicated to BEOL the fabricator and/or fabrication facility. In some applications the FEOL and BEOL processing can be implemented by the same fabricator or performed at the same fabrication facility. Accordingly, the transport 1104 may not be necessary and the wafer 1170 can continue to be processed as the wafer 1170′. The BEOL process forms the aforementioned memory elements and memory layer(s) directly on top of the base layer die 1106 to form a finished die 1199 that includes the FEOL circuitry portion 170 along the −Z axis and the BEOL memory portion along the +Z axis. For example, the memory elements (e.g., 101, 1100) and their associated WLs and BLs can be fabricated during the BEOL processing. The types of memory elements that can be fabricated BEOL are not limited to those described herein and the materials for the memory elements are not limited to the memory element materials described herein. A cross-sectional view along a dashed line BB-BB depicts a memory device die 1199 with a single layer of memory 1151 grown (e.g., fabricated) directly on top of base die 1106 along the +Z axis, and alternatively, another memory device die 1199 with three vertically stacked layers of memory 1150 grown (e.g., fabricated) directly on top of base die 1106 along the +Z. Finished die 1199 on wafer 1170′ may be tested 1174 and good and/or bad die identified. Subsequently, the wafer 1170′ can be singulated 1178 to remove die 1199 (e.g., die 1199 are precision cut or sawed from wafer 1170′) to form individual memory device die 1199. The singulated die 1199 may subsequently be packaged 1179 to form an integrated circuit chip 1190 for mounting to a PC board or the like, as a component in an electrical system (not shown) that electrically accesses IC 1190 to perform data operations on BEOL memory. Here a package 1181 can include an interconnect structure 1187 (e.g., pins, solder balls, or solder bumps) and the die 1199 mounted in the package 1181 and electrically coupled 1183 with the interconnect structure 1187 (e.g., using wire bonding or soldering). The integrated circuits 1190 (IC 1190 hereinafter) may undergo additional testing 1185 to ensure functionality and yield. The die 1199 or the IC 1190 can be used in any system requiring non-volatile memory and can be used to emulate a variety of memory types including but not limited to SRAM, DRAM, ROM, and Flash. Unlike conventional Flash non-volatile memory, the die 1199 and/or the IC's 1190 do not require an erase operation or a block erase operation prior to a write operation so the latency associated with conventional Flash memory erase operations is eliminated and the latency associated with Flash OS and/or Flash file system required for managing the erase operation is eliminated. Random access data operations to the die 1199 and/or the IC's 1190 can be implemented with a granularity of 1-bit (e.g., a single memory element) or more (e.g., a page or block of memory elements). Moreover, a battery back-up power source or other AC or DC power source is not required to retain data stored in the memory elements embedded in each memory layer (1151 or 1150) because the memory is non-volatile and retains stored data in the absence of electrical power. Another application for the IC's 1190 is as a replacement for conventional Flash-based non-volatile memory in embedded memory, solid state drives (SSD's), hard disc drives (HDD's), or cache memory, for example.

FIG. 11F graphically depicts one example of a non-linear I-V characteristic 1180 for a discrete re-writeable non-volatile two-terminal resistive memory element (e.g., the memory element 101, 1100) having integral selectivity due to its non-linear I-V characteristics and the non-linear I-V characteristic is maintained regardless of the value of the data stored in the memory cell, that is the I-V characteristic of the memory element does not change from non-linear to linear as a function of the resistive state stored in the memory element. Therefore, the non-linear I-V characteristic of the memory element is non-linear for all values of stored data (e.g., resistive states). Voltage V applied across the memory element is plotted on the Y-axis and current density J through the memory element is plotted on the X-axis. Here, current through the memory element is a non-linear function of the applied voltage across the memory element. Accordingly, when voltages for data operations (e.g., read and write voltages) are applied across the memory element, current flow through the memory element does not significantly increase until after a voltage magnitude of about 2.0V (e.g., at ≈0.2 A/cm²) is reached (e.g., a read voltage of about 2.0V across the memory element). An approximate doubling of the voltage magnitude to about 4.0V does not double the current flow and results in a current flow of ≈0.3 A/cm². The graph depicted is only an example and actual non-linear I-V characteristics will be application dependent and will depend on factors including but not limited to an area of the memory element (e.g., area determines the current density J) and the thin-film materials used in the memory element, just to name a few. The area of the memory element will be application dependent. Here, the non-linear I-V characteristic of the discrete memory element applies to both positive and negative values of applied voltage as depicted by the non-linear I-V curves in the two quadrants of the non-linear I-V characteristic 1180.

One advantage of a discrete re-writeable non-volatile two-terminal resistive memory element that has integral selectivity due to a non-linear I-V characteristic is that when the memory element is half-selected (e.g., one-half of the magnitude of a read voltage or a write voltage is applied across the memory element) during a data operation to a selected memory cell(s), the non-linear I-V characteristic is operative as an integral quasi-selection device and current flow through the memory element is reduced compared to a memory cell with a linear I-V characteristic. Therefore, a non-linear I-V characteristic can reduce data disturbs to the value of the resistive state stored in the memory element when the memory element is un-selected or is half-selected.

In some applications it may be desirable to deposit thin-film layers of material in the trenches of FIGS. 3B, 4A-4B, 6D-6H, and 7-9, that form a selection device or a non-ohmic device (NOD). Selection devices such as one or more diodes (e.g., 1D-1R, 2D-1R), transistors (e.g., 1T-1R), or NOD's such as MIM or MIIM devices have advantages and disadvantages. Advantages include improving half-select ratio for un-selected memory cells during data operations, reduction or elimination of disturbs to un-selected or half-selected memory cells, and reduction of leakage currents for half-selected memory cells, just to name a few. On the other hand, disadvantages include additional processing steps, additional mask sets and their associated costs, reduced device yield due to the additional processing steps, and higher manufacturing costs, just to name a few. Further, a memory cell that includes a selection device or NOD electrically in series with the memory element will have a voltage drop across the selection device/NOD and the memory element during data operations. The voltage drop across terminals of the memory cell must therefore be increased to account for the voltage drop across the selection device/NOD so that the voltage drop across the memory element is sufficient to read or write the memory element. Higher voltages increase power consumption and waste heat generation (power dissipation).

To that end, the memory element can optionally be electrically coupled with a selection device/NOD formed in the trench or outside of the trench. The selection device/NOD can be of the type described in U.S. patent application Ser. No. 11/881,473, filed Jul. 26, 2007, published as U.S. Pub. No. 2009/0027976, and entitled “Threshold Device For A Memory Array”; and U.S. Pat. No. 7,884,349, issued on Feb. 8, 2011, and entitled “Selection Device for Re-Writable Memory” both of which have already been incorporated herein by reference in their entirety.

The foregoing description, for purposes of explanation, uses specific nomenclature to provide a thorough understanding of the invention. However, it will be apparent to one skilled in the art that specific details are not required in order to practice the invention. In fact, this description should not be read to limit any feature or aspect of the present invention to any embodiment; rather features and aspects of one embodiment can readily be interchanged with other embodiments. Notably, not every benefit described herein need be realized by each embodiment of the present invention; rather any specific embodiment can provide one or more of the advantages discussed above. In the claims, elements and/or operations do not imply any particular order of operation, unless explicitly stated in the claims. It is intended that the following claims and their equivalents define the scope of the invention.

What is claimed is:

1. A non-volatile cross-trench memory, comprising:
at least one back-end-of-the-line (BEOL) two-terminal cross-trench memory array including
a plurality of first trenches positioned in a first dielectric layer and arranged parallel to one another, each first trench including a liner layer that partially surrounds a first conductor, a first barrier layer in contact with the liner layer and the first conductor, and a first electrode layer in contact with the first barrier layer and having a substantially planar upper surface,
a plurality of second trenches positioned in a second dielectric layer, arranged parallel to one another, and arranged orthogonally to the plurality of first trenches, each second trench including a layer of an insulating metal oxide (IMO) in contact with at least one layer of a conductive metal oxide (CMO) that includes mobile oxygen ions, a second electrode layer in contact with the CMO, a second barrier layer in contact with the second electrode layer, and a second conductor in contact with the second barrier layer, and
a plurality of discrete re-writeable non-volatile two-terminal memory elements, each memory element is positioned between a cross-point of one of the plurality of first trenches with one of the plurality of second trenches, each memory element having a portion of its respective IMO in contact with a portion of the substantially planar upper surface of the first electrode of its respective first trench, and each memory element is directly electrically in series with the first and second electrode layers at its respective cross-point.

2. The memory of claim 1, wherein each memory element includes a non-linear I-V characteristic operative to impart integral selectivity to the memory element and the non-linear I-V characteristic is retained regardless of a state of non-volatile data stored in the memory element.

3. The memory of claim 2, wherein each memory element stores at least two-bits of the non-volatile data as a plurality of conductivity profiles that can be reversibly changed by applying a write voltage across the first and second electrode layers of the memory element and the non-volatile data can be non-destructively read by applying a read voltage across the first and second electrode layers of the memory element.

4. The memory of claim 3, wherein a magnitude of the write voltage is less than 3 Volts.

5. The memory of claim 3, wherein a magnitude of the read voltage is less than 1.5 Volts and the read voltage is less than the write voltage.

6. The memory of claim 1, wherein a write operation to one or more of the memory elements does not require a prior erase operation.

7. The memory of claim 1, wherein the at least one layer of CMO comprises exactly two layers of CMO that are made from different CMO materials.

8. The memory of claim 1, wherein the at least one layer of CMO comprises exactly three layers of CMO and at least two of the three layers are made from different CMO materials.

9. The memory of claim 1, wherein the plurality of first and second trenches are electrically coupled with front-end-of-the-line (FEOL) active circuitry fabricated on a semiconductor substrate and the at least one BEOL two-terminal cross-trench memory array is in contact with and is fabricated directly above the semiconductor substrate.

10. The memory of claim 9, wherein the semiconductor substrate comprises a silicon substrate.

11. The memory of claim 10, wherein the silicon substrate comprises a silicon wafer.

12. The memory of claim 10, wherein the silicon substrate comprises a silicon die.

13. The memory of claim 1, wherein the plurality of memory elements can be individually accessed for a data operation at a granularity of one bit or more.

14. The memory of claim 1, wherein the layer of IMO has a thickness that is less than 50 Angstroms.

15. The memory of claim 1, wherein the at least one layer of CMO comprises at least two distinct CMO layers and at least one of the at least two distinct CMO layers has a thickness that is less than 50 Angstroms.

16. The memory of claim 1, wherein one or more of the plurality of memory elements comprise programmed memory elements and a portion of the mobile oxygen ions in the CMO of the programmed memory elements are disposed in the IMO of the programmed memory elements.

17. The memory of claim 1, wherein one or more of the plurality of memory elements comprise erased memory elements and substantially all of the mobile oxygen ions are disposed in the CMO of the erased memory elements.

18. The memory of claim 1, wherein during a write operation to one or more of the plurality of memory elements a portion of the mobile oxygen ions are transported between the CMO and the IMO of the memory elements that are being written to during the write operation.

19. The memory of claim 1, wherein mobile oxygen ions disposed in portions of the at least one layer of CMO that are not positioned between the cross-point of one of the plurality of first trenches with one of the plurality of second trenches remain substantially stationary during write operations to one or more of the plurality of memory elements.

20. A multi-layer non-volatile cross-trench memory, comprising:
a silicon substrate including active circuitry fabricated on the silicon substrate and at least a portion of the active circuitry configured to perform data operations on vertically fabricated back-end-of-the-line (BEOL) non-volatile memory; and
a plurality of vertically stacked BEOL memory layers that are in contact with one another and are monolithically fabricated directly above and are integrally connected with the silicon substrate, each BEOL memory layer including
at least one back-end-of-the-line (BEOL) two-terminal cross-trench memory array, each memory array including
a plurality of first trenches positioned in a first dielectric layer and arranged parallel to one another, each first trench including a liner layer that partially surrounds a first conductor, a first barrier layer in contact with the liner layer and the first conductor, and a first electrode layer in contact with the first barrier layer and having a substantially planar upper surface,
a plurality of second trenches positioned in a second dielectric layer, arranged parallel to one another, and arranged orthogonally to the plurality of first trenches, each second trench including a layer of an insulating metal oxide (IMO) in contact with at least one layer of a conductive metal oxide (CMO) that includes mobile oxygen ions, a second electrode layer in contact with the CMO, a second barrier layer in contact with the second electrode layer, and a second conductor in contact with the second barrier layer, the plurality of first and second trenches are electrically coupled with the active circuitry, and
a plurality of discrete re-writeable non-volatile two-terminal memory elements, each memory element is positioned at a cross-point of one of the plurality of first trenches with one of the plurality of second trenches, each memory element having a portion of its respective IMO in contact with a portion of the substantially planar upper surface of the first electrode of its respective first trench, and each memory element is directly electrically in series with the first and second electrode layers at its respective cross-point,
wherein memory elements in adjacent memory planes electrically share one of the plurality of first trenches, one of the plurality of second trenches, or both.

21. The memory of claim 20, wherein the silicon substrate is selected from the group consisting of a silicon wafer and a silicon die.

22. The memory of claim 20, wherein mobile oxygen ions disposed in portions of the at least one layer of CMO that are not positioned between the cross-point of one of the plurality of first trenches with one of the plurality of second trenches remain substantially stationary during write operations to one or more of the plurality of memory elements.
